(19) United States
(12) Patent Application Publication
(10) Pub. No.: US 2016/0260544 A1
(43) Pub. Date: Sep. 8, 2016

(54) FLEXIBLE DIELECTRIC STRUCTURE AND METHOD OF MAKING SAME

(71) Applicant: Lockheed Martin Corporation, Bethesda, MD (US)

(72) Inventor: Shashishekar P. Adiga, Mount Laurel, NJ (US)

(21) Appl. No.: 14/640,867

(22) Filed: Mar. 6, 2015

(51) Int. Cl. H01G 4/06; H01L 29/51; H01G 4/012; H01G 4/30; H01G 4/33; H01L 29/786; H01L 49/02

(52) U.S. Cl. CPC H01G 4/06; H01L 29/786; H01L 29/513; H01L 28/40; H01G 4/30; H01G 4/33; H01G 4/012; H01L 2029/42388

(57) ABSTRACT

A flexible dielectric structure includes alternating polymer layers having a high density of nanoparticles and polymer layers having a low density of nanoparticles. The nanoparticles may be conductors or dielectrics, and may include metals, ceramics and carbon nanoparticles. The polymer layers may include sublayers of polymers alternating on a layer-by-layer basis between complementary properties of hydrogen bond acceptor and hydrogen bond donor.

### FIELD OF THE INVENTION

The present disclosure relates generally to structures having a high dielectric constant, and more specifically to flexible polymeric structures having a high dielectric constant.

### BACKGROUND

Polymeric dielectrics are employed in a variety of electronic applications, including applications where flexible components are desirable. One such example is the gate dielectric in thin film transistors. There is a great need in printed and flexible electronics applications for dielectric compositions which permit organic transistors to operate at lower voltages, and thus at reduced power requirements. The prior art options for flexible film dielectrics are polymers that typically possess a dielectric constant between 2 and 4. To improve the dielectric constant of polymeric films composite formulations have been explored in which a material of high dielectric constant is dispersed in a polymer matrix. In the prior art, for example, dielectric materials include a polymeric matrix with a high dielectric constant material, such as particles having a size of about 50 nanometers of barium titanium oxide, titanium dioxide and silicon dioxide, substantially evenly distributed throughout the matrix. Exemplary polymers employed in such materials include polymethylmethacrylate, polycarbonate, polyester, and PVDF. These materials may achieve desired mechanical characteristics and a desired dielectric constant using a polymeric matrix material and a high dielectric constant material. However, these materials have disadvantages, including low breakdown voltages and limits on available ranges of dielectric constant. The low breakdown voltage and leakage stem from the fact that the significant volume fractions of high dielectric constant particles required to impart beneficial dielectric constant to the matrix lead to enhanced local field intensities and percolating conducting paths in the insulating matrix.

Alternative structures that include properties of polymeric dielectrics, such as flexibility, while providing other desirable properties not present in prior art polymeric dielectrics, such as higher dielectric constants and while minimizing local field intensities and/or percolating paths and that do not compromise breakdown strength of the insulating matrix, are desired.

Desirable properties of such alternative structures may include: no leakage current or negligible leakage current; high breakdown voltages, and the capacity to inject charge carriers into the active semiconducting medium to facilitate low-power operation. Further desirable properties of such compositions include compatibility with organic transistor systems, and with roll-to-roll manufacturing processes. Preferably, such compositions will be formable into continuous layers that are less than 3 microns thick.

### SUMMARY

In one embodiment, a polymeric structure having properties including high dielectric constant and relatively high breakdown voltage is provided. In such an embodiment, a flexible dielectric structure includes a first polymer layer having a low density of nanoparticles; a second polymer layer on and in contact with the first polymer layer and having a high density of nanoparticles; and a third polymer layer on and in contact with the second polymer layer and having a low density of nanoparticles.

In an embodiment, a method of making a flexible dielectric structure includes forming a first polymer layer having a low density of nanoparticles, forming, directly on the first polymer layer, a second polymer layer having a high density of nanoparticles, and forming, directly on the second polymer layer, a third polymer layer having a low density of nanoparticles. In embodiments, each of the first polymer layer, the second polymer layer, and the third polymer layer may be made by applying alternating layers of polymers that are hydrogen bond donors and polymers that are hydrogen bond acceptors. At the interfaces between the respective high density of nanoparticles layers and low density of nanoparticles layers, the layers are maintained bonded to one another by hydrogen bonds, as a result of matrix polymers have complementary hydrogen bond acceptor and hydrogen bond donor properties. In embodiments, one or more of the first polymer layer, the second polymer layer, and the third polymer layer may be formed of a single layer of a polymer being a hydrogen bond donor or a hydrogen bond acceptor.

In an embodiment, a transistor on a flexible substrate includes a gate formed on the flexible substrate, a gate dielectric on the gate, the gate dielectric including a first polymer layer having a low density of nanoparticles; a second polymer layer on the first polymer layer and having a high density of nanoparticles; and a third polymer layer on the second polymer layer and having a low density of nanoparticles. The transistor further includes a source, drain, and semiconductor material formed on the gate dielectric.

In an embodiment, a film capacitor includes a flexible dielectric and first and second planar flexible conductive electrodes on opposing faces of the dielectric. The flexible dielectric includes a first polymer layer having a low density of nanoparticles; a second polymer layer on the first polymer layer and having a high density of nanoparticles; and a third polymer layer on the second polymer layer and having a low density of nanoparticles.

In embodiments, each of the high density of nanoparticle layers and the low density of nanoparticle layers include alternating layers of polymers having hydrogen bond acceptor properties and polymers having hydrogen bond donor properties.

When compared to composite dielectrics with uniformly dispersed nanoparticles in a polymer matrix, embodiments of the present disclosure exhibit higher breakdown voltages. The relatively higher breakdown voltages may be a result of a lack of continuous conducting paths through the layers of relatively low density of conductive nanoparticles, thus preventing breakdown at low voltages.

### BRIEF DESCRIPTION OF THE DRAWINGS

FIG. 1 is a cross-sectional view of a flexible dielectric structure according to an embodiment of the present disclosure.

FIG. 2 is a cross-sectional view of a flexible dielectric structure according to another embodiment of the present disclosure.

FIG. 3, an exemplary cross-sectional view of an embodiment of a flexible dielectric structure having oriented rod-like nanoparticles is shown.

FIG. 4 is an isometric view of a flexible dielectric structure of FIG. 2.

FIG. 5 shows an exemplary transistor incorporating a flexible dielectric material as a gate dielectric according to an embodiment.

FIG. 6 is a graph showing simulation results of varying thickness of layers having a high density of nanoparticles in a flexible dielectric structure.

FIG. 7 is a graph showing simulation results of varying thickness of layers having a low density of nanoparticles in a flexible dielectric structure.

FIG. 8 is a graph showing simulation results of prior art flexible dielectric structures and an exemplary dielectric structure of the present disclosure.

FIG. 9 shows a cross-sectional view of an exemplary film capacitor having a flexible dielectric material as a dielectric according to an embodiment.

### DETAILED DESCRIPTION

It is to be understood that the figures and descriptions of the present invention have been simplified to illustrate elements that are relevant for a clear understanding of the present invention, while eliminating, for purposes of clarity, many other elements found in polymers used as dielectrics, elements known in nanoparticles, and elements of methods and processes for forming polymeric structures. However, because such elements are well known in the art, and because they do not facilitate a better understanding of the present invention, a discussion of such elements is not provided herein. The disclosure herein is directed to all such variations and modifications known to those skilled in the art.

In the following detailed description, reference is made to the accompanying drawings that show, by way of illustration, specific embodiments in which the invention may be practiced. It is to be understood that the various embodiments of the invention, although different, are not necessarily mutually exclusive. Furthermore, a particular feature, structure, or characteristic described herein in connection with one embodiment may be implemented within other embodiments without departing from the scope of the invention. In addition, it is to be understood that the location or arrangement of individual elements within each disclosed embodiment may be modified without departing from the scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout several views.

Embodiments of the present disclosure include improved polymeric structures having properties of flexibility as well as high dielectric constant and high breakdown voltages.

In embodiments, structures include a plurality of alternating polymeric layers, in which first alternating layers having a dielectric, flexible polymeric matrix having no nanoparticles or a low density of nanoparticles, and second alternating layers having a high density of nanoparticles.

Advantageously, selection of the volume fraction of nanoparticles in the high density layers, selection of nanoparticle materials, and selection of thicknesses of the respective layers provides for precise selection of the dielectric properties of the structure.

A “layer” as used herein is of a material having uniform or substantially uniform thickness between opposing major planar surfaces.

A “nanoparticle” as used herein is a particle having a maximum dimension or feature size of about 10 nanometers to about 100 nanometers in diameter. Nanoparticles shaped as rods may have a greater dimension along a long axis, and may have a length up to 500 nanometers. The aspect ratio, i.e., ratio of length to diameter, of a rod like nanoparticle, may be in the range of 10 to 50, by way of non-limiting example. In some embodiments, the feature size of the nanoparticles may be up to 100 nm.

A low density of nanoparticles is from no nanoparticles to a density below the percolation threshold of the nanoparticles in the layer. The percolation threshold is a volume percentage of nanoparticles in the polymer matrix at which the layer become electrically conductive. The percolation threshold is dependent on factors including shape of the nanoparticles, aspect ratio, and alignment. For example, the percolation threshold is typically lower for randomly oriented rod-shaped nanoparticles, or for randomly-oriented nanoflakes, than for aligned rod-shaped nanoparticles, aligned nanoflakes, or spheres. For randomly oriented rod-shaped nanoparticles, the percolation threshold typically decreases as the aspect ratio of the rods increases. By way of example, a percolation threshold of about 28% by volume of spheres in a matrix is possible. Thus, in embodiments, the volume percentage of spherical nanoparticles in the low density layers may be less than 28%. In embodiments, the volume density of spherical nanoparticles may be any value between zero and 28%, such as 5%, 10%, 15%, 20% or 25%, or up to and including any of 5%, 10%, 15%, 20% or 25%.

Portions of a low density of nanoparticles layer adjacent a high density of nanoparticles layer may receive additional nanoparticles from the high density layer, resulting in a higher density near the interface. Accordingly, a volume percentage of nanoparticles in the low density of nanoparticles layer may be substantially less than a percolation threshold, in order to prevent the percolation threshold from being reached near the interface as nanoparticles cross the interface from a high density of nanoparticles layer.

The volume percentage of nanoparticles in a high density of nanoparticles layer may be as high as possible consistent with mechanical integrity of the polymer matrix. Thus, in embodiments, the volume density of nanoparticles in a high density of nanoparticles layer may be any of 10%, 20%, 30%, 40%, 50%, 60% and 70%, as well as any intermediate volume densities.

The volume density of nanoparticles in the high density of nanoparticles layers is higher than the volume density of nanoparticles in the low density of nanoparticles layers. Embodiments may include a wide variety of combinations of volume densities of nanoparticles. Thus, the volume density of the low density of nanoparticles layer may be from 0% to the percolation threshold. The volume density of the high density of nanoparticles layer may be from above the volume density of the low density of nanoparticle layers to the maximum density consistent with mechanical integrity of the polymer matrix.

By way of non-limiting example, the volume density of nanoparticles in the low density of nanoparticles layers may be 0, and the volume density of nanoparticles in the high density of nanoparticles layers may be 10% or greater. By way of non-limiting example, the volume density in the low density of nanoparticles layers may be 6% or less, and the volume density in the high density of nanoparticles layers may be 10% or greater. By way of non-limiting example, the volume density of nanoparticles in the low density of nanoparticles layers may be 10% or less, and the volume density of nanoparticles in the high density of nanoparticles layers may be 15% or greater. By way of non-limiting example, the volume density in the high density of nanoparticles layer may be at least 4%, 10%, 15%, 20%, 25%, 30%, 35% or 40%, or any intermediate percentage, as a volume percentage of nanoparticles, greater than the volume density of nanoparticles in the low density of nanoparticles layers.

In embodiments, each of the high density of nanoparticle layers and the low density of nanoparticle layers are made up of a plurality of sublayers, in which each of the sublayers are joined at their interfaces by hydrogen bonding. Similarly, the high density of nanoparticle layers and the low density of nanoparticle layers are joined at their interfaces by hydrogen bonds, the sublayers at the interfaces having complementary hydrogen bond donors and hydrogen bond acceptors.

Generally, one material has an excess of functional groups that behave as proton donors, such as hydroxyl, carboxyl, amine or amide groups. The complementary material has an excess of functional groups that behave as electron acceptors, such as carbonyl, ether or hydroxyl groups, and nitrogen atoms on amines and heterocyclic groups. Exemplary pairs of materials for the respective pairs of sublayers of the polymeric matrix include, with the hydrogen bond donor being the first and the hydrogen bond acceptor being the second in each pair:

1. Poly(ethylene oxide)-poly(methacrylic acid)

2. Poly(ethylene oxide)-poly(acrylic acid)

3. Poly(vinylpyrrolidone)-poly(methacrylic acid)

4. Poly(vinylpyrrolidone)-poly(acrylic acid)

5. Poly(ethylene oxide)-poly(aniline)

6. Poly(vinylpyrrolidone)-poly(aniline)

7. Poly(vinyl alcohol)-poly(aniline)

8. Poly(acrylamide)-poly(aniline)

In embodiments, each sublayer making up the high density of nanoparticle layers and low density of nanoparticle layers, in a dielectric structure having 3 or more layers, may be of one of the two polymers in one of the foregoing pairs. In other embodiments, in a dielectric structure, sublayers may be of three or more polymers, so long as adjacent polymer sublayers have complementary hydrogen bond donor and hydrogen bond acceptor properties.

By way of example, a layer may include alternating sublayers of poly(ethylene oxide) and of one of poly(methacrylic acid) and poly(acrylic acid).

In embodiments, the polymer layers and sublayers may include alternating layers of other polymers having complementary properties that facilitate bonds at the interfaces.

In embodiments, the polymer layers may be of electrically insulating polymers.

Exemplary materials for the nanoparticles include metals, carbon, ceramics, conducting polymers, and conjugated polymers, and combinations of two or more of metals, carbon, conducting polymers, conjugated polymers and ceramics.

Nanoparticles of metal or containing metal may be composed entirely or in part of, by way of non-limiting example: gold, copper, silver, aluminum, titanium, palladium, platinum, zinc, tin, tantalum, molybdenum, manganese, nickel and alloys including two or more of the foregoing metals. Nanoparticles may also be composed of mixtures including two or more of the foregoing metals. The metals listed are only exemplary, and nanoparticles may be of other metals, alloys including one or more of the above metals and one or more other metals, and alloys of two or more metals other than the above metals, by way of example.

Nanoparticles composed of or including carbon may include carbon black, carbon nanotubes, graphene platelets, graphene nanoflakes, graphitic nanoflakes, carbon nanowalls, carbon nanofibers, and carbon onions. In embodiments, nanoparticles may be at least one of carbon black, carbon nanotubes, graphene platelets, graphene nanoflakes, graphitic nanoflakes, carbon nanowalls, carbon nanofibers, and carbon onions. Carbon onions, as used herein, are nested shells of pure carbon and include, by way of example, nested polyhedral structures. Other forms of pure carbon may also be employed. Nanoparticles may include carbon and one or more other elements in addition to carbon.

Exemplary conducting polymers, of which nanoparticles may be composed, include polyaniline (PANI), polypyrrole (PPy), polythiophene (PTh), polynathylamine (PNA) and their respective derivatives. In embodiments, nanoparticles may be at least one of polyaniline (PANI), polypyrrole (PPy), polythiophene (PTh), polynathylamine (PNA) and their respective derivatives. Conjugated polymers may include conducting polymers and semiconducting polymers. In embodiments, insulating polymer layers may have inclusions of conducting polymers and semiconducting polymers in addition to nanoparticles or as an alternative to nanoparticles.

Exemplary ceramic materials include oxides of barium, titanium, silicon and aluminum. By way of further example, ceramic materials may include CaCu₃Ti₄O₁₂ (CCTO), BaTiO₃, TiO₂, SiO₂ and Al₂O₃. Nanoparticles of ceramic may be composed of two or more of the foregoing ceramic materials, other ceramic materials, and combinations of one or more of the foregoing materials and other ceramic materials.

Exemplary dimensions of the layers include a thickness between 40 nm and 200 nm, including any thickness intermediate 40 nm and 200 nm.

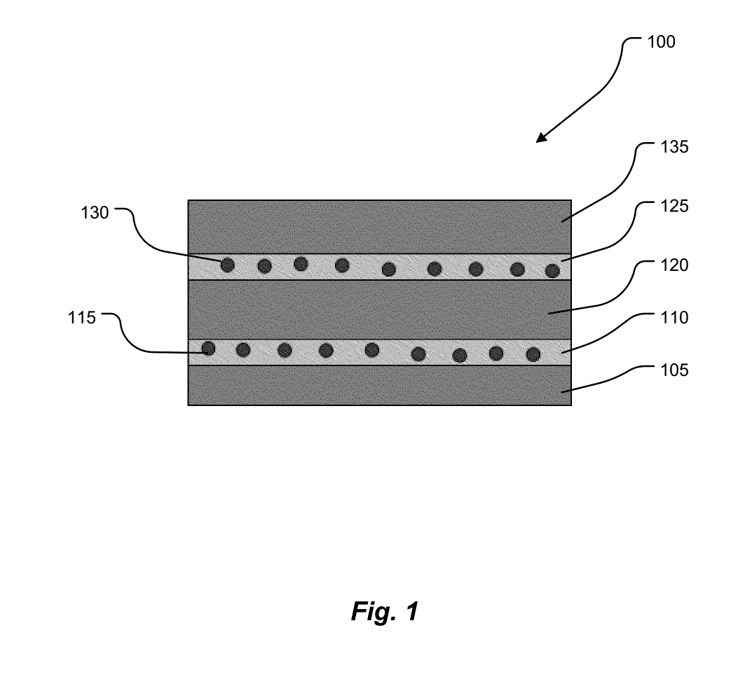

Referring to FIG. 1, an exemplary cross-sectional view of a dielectric structure according to an embodiment is shown. Dielectric structure 100 includes a first polymer layer 105 having a low density of nanoparticles. The low density of nanoparticles may be zero, for example. Second polymer layer 110 is directly on, in contact with and has a planar interface with first polymer layer 105. Second polymer layer 110 has a high density of nanoparticles 115, such as a volume density of between 10 and 40 percent. The nanoparticles 115 may be of metal, ceramic, carbon or other conductive or dielectric materials. Nanoparticles 115 may be generally spherical. Third polymer layer 120 has a low density of nanoparticles, such as zero, and is directly on second polymer layer and has a planar interface with second polymer layer 110. Fourth polymer layer 125 is directly on and in contact with third polymer layer 120 and has a planar interface with third polymer layer 120, and has a high density of nanoparticles 130. Fifth polymer layer 135 is directly on and in contact with fourth polymer layer 125 and has a low density of nanoparticles.

First, second, third, fourth and fifth polymer layers 105, 110, 120, 125, 135 may each be made up of multiple alternating polymer sublayers of polymers that are hydrogen bond donors and hydrogen bond acceptors. The sublayers may have thicknesses between about 15 nanometers and about 400 nanometers. In embodiments, one or more of the first, second, third, fourth and fifth polymer layers 105, 110, 120, 125, 135 may be of a single layer of a polymer that is either a hydrogen bond donor or a hydrogen bond acceptor, and the layers may alternate. For example, if first polymer layer 105 is of a polymer that is a hydrogen bond donor, then second polymer layer 110 is of a different material that is a hydrogen bond acceptor. Similarly, if first polymer layer 105 is of a polymer that is a hydrogen bond acceptor, then second polymer layer 110 is of a different material that is a hydrogen bond donor.

In embodiments, throughout the dielectric structure, all of the sublayers, or layers, may be made up of two alternating polymers, having complementary hydrogen bond acceptor/donor properties. In embodiments, the matrix polymers may be of any of the exemplary pairs of materials listed above, or of other pairs of polymers having similar complementary hydrogen bond donor/hydrogen bond acceptor properties. For example, alternating complementary sublayers may be of poly(ethylene oxide) and one of poly(methacrylic acid), poly(acrylic acid) and poly(aniline). In embodiments, the dielectric structure may include more than one type of sublayer or layer of either or both of the hydrogen bond acceptor or hydrogen bond donor type. In embodiments, a single sublayer or layer may include more than one polymer of a same hydrogen bond acceptor or hydrogen bond donor type.

The two high density of nanoparticle layers, alternating with three low density of nanoparticle layers, are merely exemplary. The numbers of alternating layers are not limited. In embodiments, for example, up to ten high density of nanoparticle layers may be included, alternating with low density of nanoparticle layers. In embodiments, more than ten high density of nanoparticle layers may be included in a dielectric structure according to an embodiment.

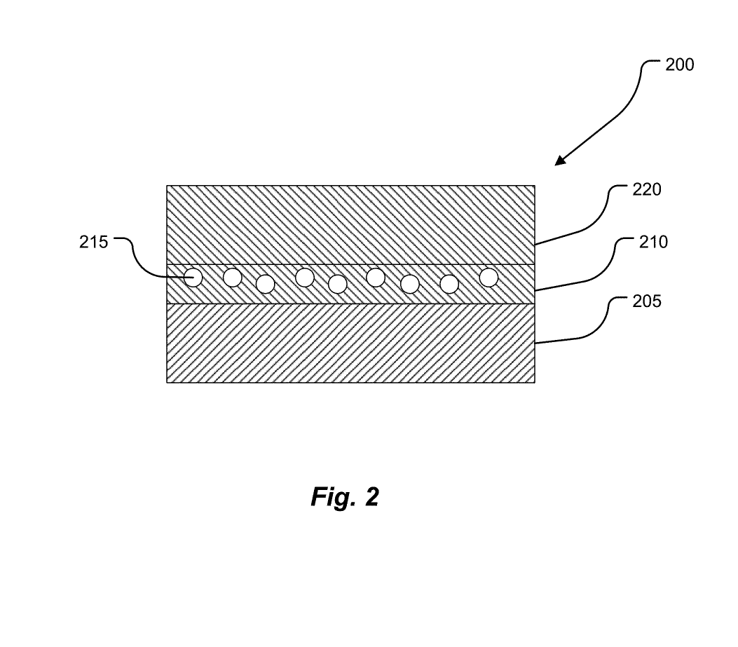

Referring to FIG. 2, an exemplary cross-sectional view of a dielectric structure according to an alternative embodiment is shown. In this embodiment, there is one and only one high density of nanoparticle layer 210. Layer 210 is intermediate first polymer layer 205, which has a low density of nanoparticles, and third polymer layer 220, which also has a low density of nanoparticles. Nanoparticles 215 are shown schematically in high density nanoparticle layer 210. Advantages of the present disclosure may be achieved with the embodiment of FIG. 2, having one and only one high density of nanoparticle layer.

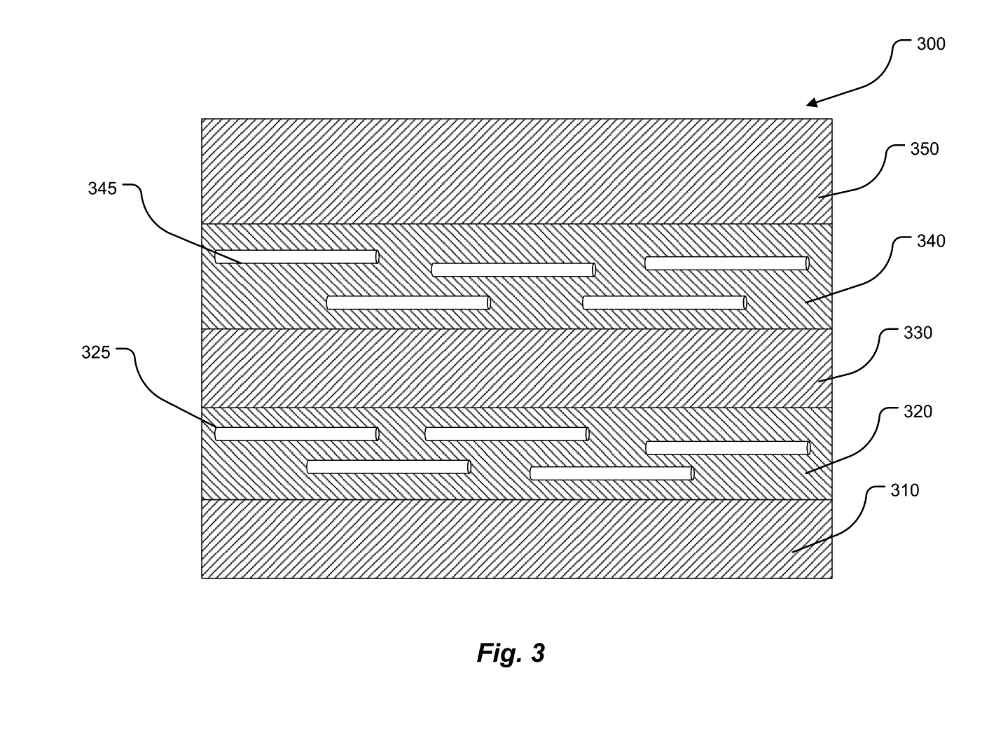

Referring to FIG. 3, an exemplary cross-sectional view of an embodiment of a dielectric structure having oriented rod-like nanoparticles is shown. Dielectric structure 300 includes a first polymer layer 310 having a low density of nanoparticles. The low density of nanoparticles may be zero, for example. Second polymer layer 320 is directly on, in contact with and has a planar interface with first polymer layer 310. Second polymer layer 320 has a high density of nanoparticles 325, which are in the form of aligned elongated rods. The nanoparticles 325 may have an aspect ratio, of length to diameter, of at least 10 to 1. Nanoparticles 325 may be of metal, ceramic, carbon, conductive polymer or other conductive or dielectric materials, and may have a volume density of between 10 and 40 percent. Nanoparticles 325 may be carbon nanotubes, for example. Alignment may be achieved by application of suitable magnetic or electrostatic fields during and/or immediately application of a polymer layer, but before setting of the polymer layer, via spin coating, dipping, or otherwise. Third polymer layer 330 has a low density of nanoparticles, such as zero, is directly on second polymer layer 320 and has a planar interface with second polymer layer 320. Fourth polymer layer 340 is directly on and in contact with third polymer layer 330 and has a planar interface with third polymer layer 330, and has a high density of aligned elongated rod-shaped nanoparticles 345, which may be the same as nanoparticles 325. Fifth polymer layer 350 is directly on and in contact with fourth polymer layer 340 and has a low density of nanoparticles.

First polymer layer 310, second polymer layer 320, third polymer layer 330, fourth polymer layer 340 and fifth polymer layer 350 may each be of multiple alternating sublayers of polymers having complementary hydrogen bond donor properties, and hydrogen bond acceptor properties. The sublayers at the respective interfaces may also have complementary hydrogen bond donor and hydrogen bond acceptor properties. In other embodiments, one or more of the layers 310, 320, 330, 340, 350 may be of a single layer of a polymer having hydrogen bond donor or hydrogen bond acceptor properties, the respective layers or sublayers at the interfaces having complementary hydrogen bond donor and hydrogen bond acceptor properties. In embodiments, the sublayers or layers may alternate between the same two materials. In embodiments, sublayers or layers may be made up of more than two materials, so long as the materials are arranged so that the hydrogen bond donor and hydrogen bond acceptor type materials are in alternating sublayers or alternating layers. In embodiments, the polymers may be of any of the exemplary pairs of materials listed above, or of other pairs of polymers having similar complementary hydrogen bond donor/hydrogen bond acceptor properties.

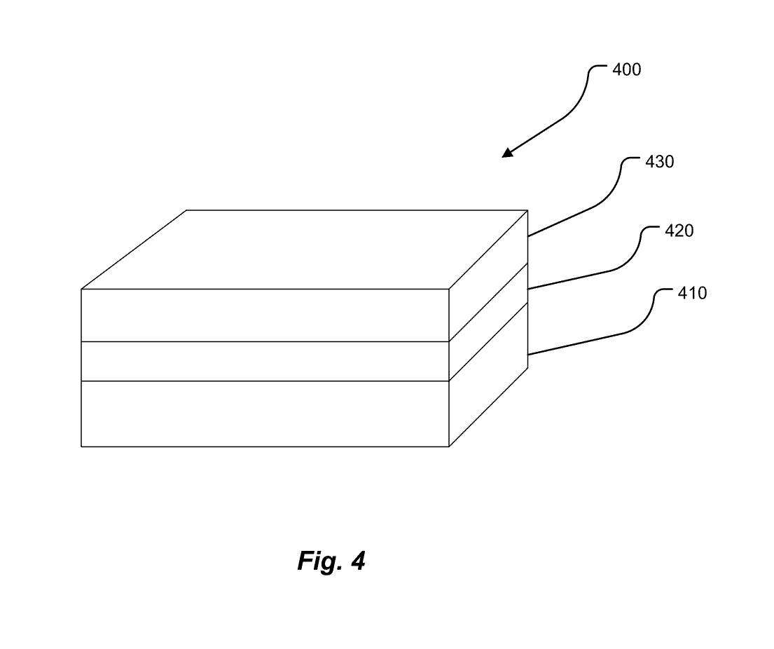

FIG. 4 is an exemplary isometric view of a dielectric structure 400. For simplicity of illustration, dielectric structure 400 is similar to dielectric structure 200 of FIG. 2, as having only one high density of nanoparticle layer 420, between low density of nanoparticle layers 410, 430.

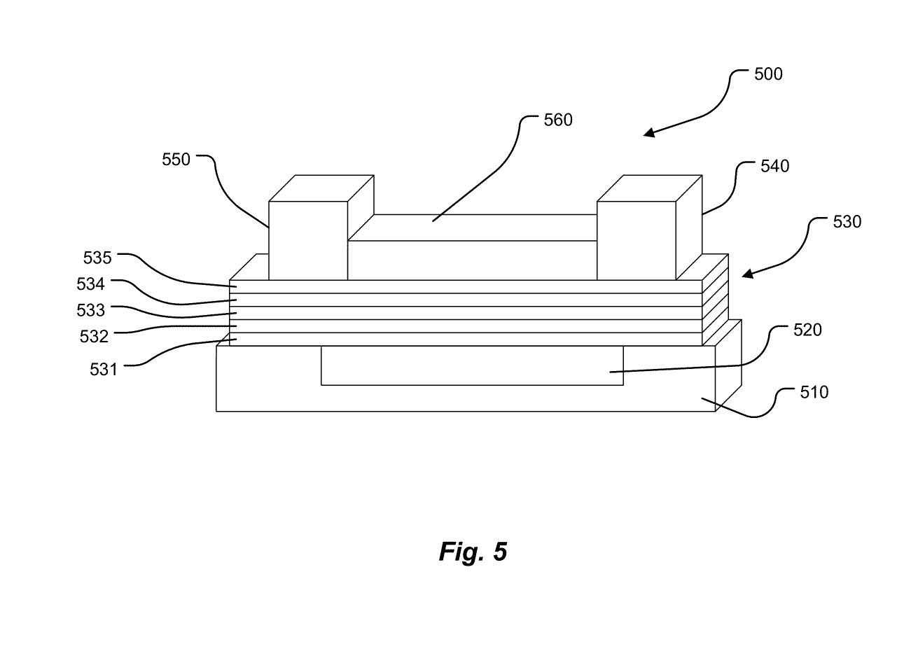

Referring to FIG. 5, an exemplary transistor incorporating a dielectric structure according to an embodiment is shown. Transistor 500 is formed on flexible substrate 510. Gate 520 is defined in flexible substrate 510. Gate dielectric 530, of a multi-layer polymer dielectric structure according to an embodiment of the present disclosure, is defined on gate 520. Gate dielectric 530, for purposes of illustration, has five polymer layers, including two high-density of nanoparticle polymer layers 532, 534, and three low-density of nanoparticle polymer layers 531, 533, 535. The number of polymer layers may be as few as three, as shown in the embodiment of FIG. 2, for example, or any higher number of polymer layers. For example, gate dielectric 530 may further include a sixth polymer layer, having a high density of nanoparticles on low-density of nanoparticle polymer layer 535; and a seventh polymer layer, having substantially no nanoparticles, on the sixth polymer layer.

Semiconductor material 560 is shown on gate dielectric 530. Source 540 and drain 550 are shown formed on gate dielectric 530 and in contact with semiconductor material 560.

Advantageously, gate dielectric 530 is flexible, and thus may flex when flexible substrate 510 is flexed. In accordance with embodiments of the present disclosure, gate dielectric 530 may have suitable properties selected based on the dimensions of layers, numbers of layers, types of nanoparticles, and density of nanoparticles in the layers.

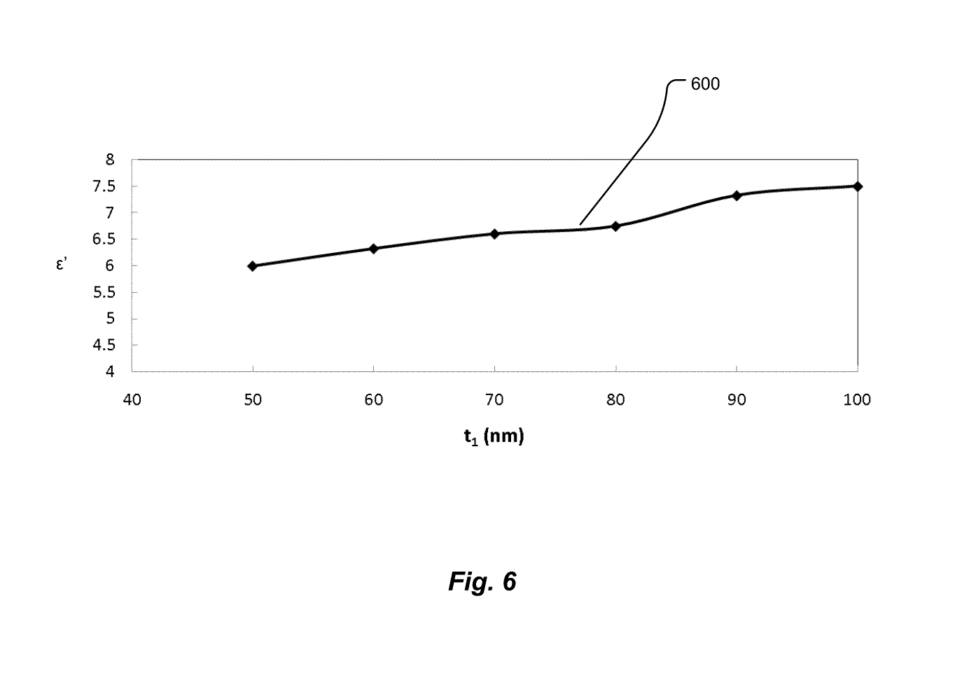

Referring now to FIG. 6, a graph is shown of results of simulations of a dielectric structure having three high-density of nanoparticle, or nanoparticle rich, layers, alternating with four low density of nanoparticle, or nanoparticle poor, layers. In this embodiment, the thickness of the four low density of nanoparticle layers (t2) is 50 nanometers. The nanoparticles are of gold, spherical, and have a radius of 15 nm. The volume density of nanoparticles in the high density nanoparticle layers, φ_{NP, 1}, is 25%. The volume density of nanoparticles in the low density nanoparticle layers, φ_{NP, 2}, is 0%. The value of the real part of the dielectric function, or permittivity, ∈′, was determined for thicknesses of the nanoparticle rich film (t1) of 50 nm, 60 nm, 70 nm, 80 nm, 90 nm and 100 nm. As indicated in FIG. 6, the real part of the dielectric function, 600, was determined to be about 6 farads per meter (f/m) for a thickness of each of the three nanoparticle rich film layers of 50 nm, increasing to about 7.5 f/m for a thickness of each of the three nanoparticle rich film layers of 100 nm. Thus, a suitable dielectric constant may be selected by adjusting the thickness of the nanoparticle rich film layers.

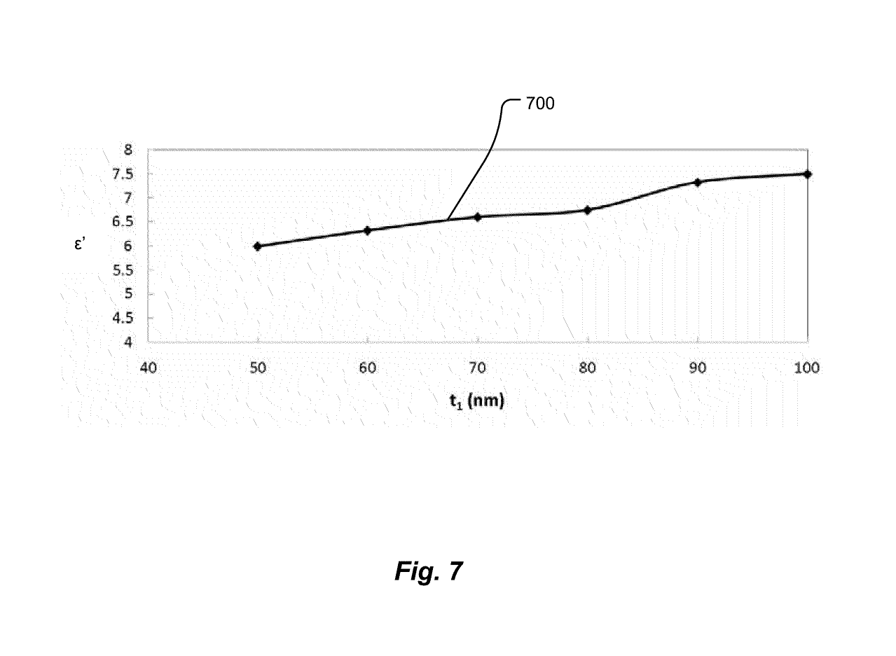

Referring now to FIG. 7, a graph is shown, similar to FIG. 6, of results of simulations of a dielectric structure having three high-density of nanoparticle, or nanoparticle rich, layers, alternating with four low density of nanoparticle, or nanoparticle poor, layers. In this embodiment, the thickness of the three high density of nanoparticle layers (t1) is 100 nanometers. The nanoparticles are of gold, spherical, and have a radius of 15 nm. The volume density of nanoparticles in the high density nanoparticle layers, φ_{NP, 1}, is 50%; the volume density of nanoparticles in the low density nanoparticle layers, φ_{NP, 2}, is 0%. The value of the real part of the dielectric function c′ was determined for thicknesses (t2) of the nanoparticle poor layers of 50 nm, 60 nm, 70 nm, 80 nm, 90 nm and 100 nm. As indicated in FIG. 7, at 700, the real part of the dielectric function was determined to be about 8 f/m for a thickness of each of the four nanoparticle poor film layers of 50 nm, decreasing to about 6 f/m at 100 nm. Thus, a suitable dielectric constant may also be selected by adjusting the thickness of the nanoparticle poor polymer film layers.

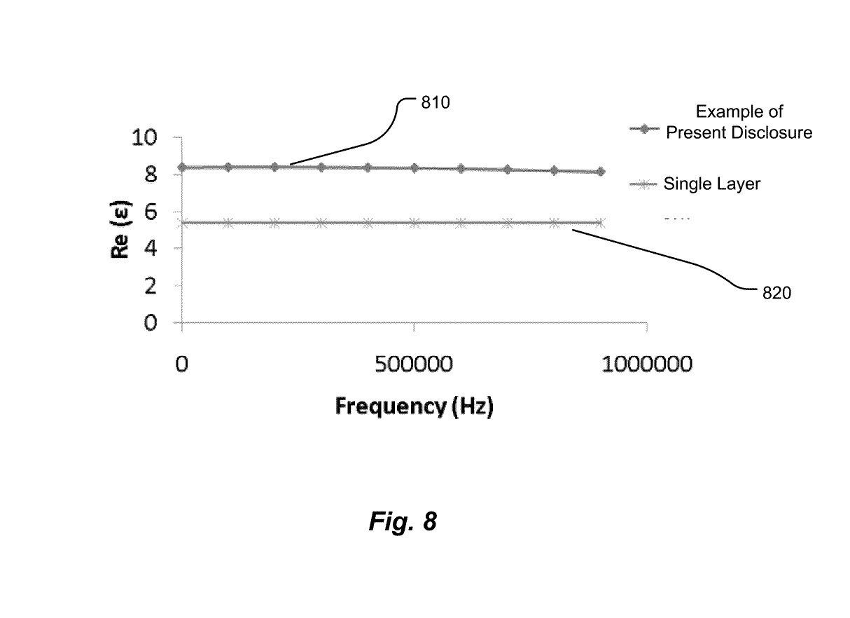

Referring to FIG. 8, a graph is shown comparing simulation results comparing an embodiment of a dielectric structure according to the present disclosure with a prior art dielectric structure of a single layer polymer with substantially uniform distribution of nanoparticles. The dielectric structure according to the present disclosure included alternating high density nanoparticle layers of 100 nm thickness, zero density nanoparticle layers of 50 nm thickness, nanoparticles of gold having a radius of 15 nm, and a volume density of nanoparticles in the high density nanoparticle layers of 12%. The resulting real part of the permittivity values are shown at 810. By comparison, the results of the simulation of the prior art structure, of a single layer polymer also loaded with 12% by volume of 15 nm radius spherical gold nanoparticles, shown at 820, provides a substantially lower real part of the permittivity.

A process of manufacturing a multilayer material according to an embodiment will now be described. The following process may be carried out by techniques such as any one of dip coating, spin coating, spray coating and ink jet printing. On a suitable substrate, such as a planar metal or ceramic platform, a first sublayer of a polymer, with no nanoparticles or only a low density of nanoparticles, is applied. The first sublayer is of a polymer material that is one of a hydrogen bond donor and a hydrogen bond acceptor. The first layer is cured to define a planar layer of uniform thickness between about 15 and about 500 nm. A second polymer, of a different polymer than the first sublayer, is applied directly on the first sublayer, with no intervening or intermediate layer. The second polymer is of a polymer material that serves to complement the hydrogen bond donor or hydrogen bond acceptor type of the first polymer layer, so that hydrogen bonds are formed between the two layers at the planar interface between the layers. The second polymer layer also has a low volume density of nanoparticles. The second layer is cured, to define a second planar sublayer of uniform thickness between about 15 and about 500 nm, with a low density of nanoparticles. The process is repeated, with alternating polymers having hydrogen bond donor and hydrogen bond acceptor properties, until a first polymer layer having a low density of nanoparticles, or no nanoparticles, is defined. A second layer, having a high density of nanoparticles, is similarly defined, directly on the first layer, by application of multiple sublayers of polymers having alternating properties of hydrogen bond acceptors and donors. In an embodiment, a suitable magnetic field or electrostatic field may be applied before each sublayer of the second layer is cured to align elongated nanoparticles, such as carbon nanotubes or elongated rods of metal or other material. A third polymer layer, having a low density of nanoparticles, may then be defined, directly on the second polymer layer, by application and curing of multiple sublayers of polymers having alternating properties of hydrogen bond acceptor and donors. In embodiments, the first, second and third polymer layers may each be made up of a single sublayer of a polymer. The steps of forming a high density of nanoparticles layer and low density of nanoparticle layers may be repeated. The resulting dielectric structure may then be removed from the underlying substrate and cut to desired dimensions for use in transistors and other devices on flexible substrates.

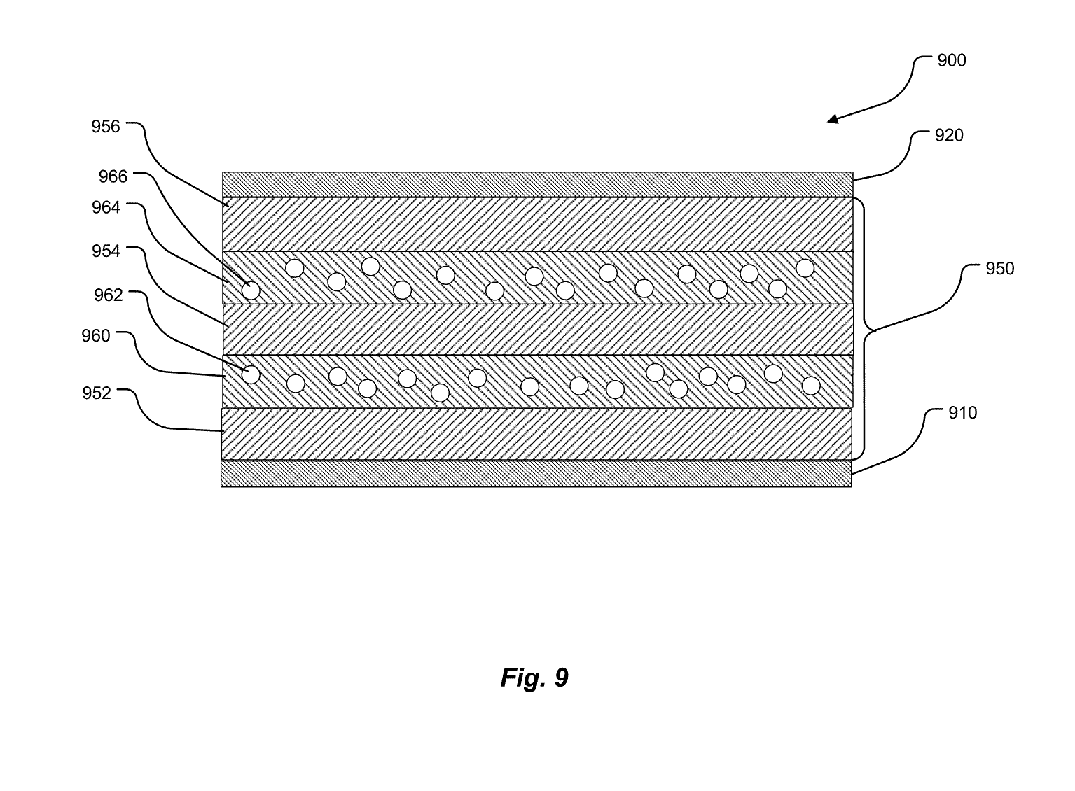

Referring to FIG. 9, a cross-sectional view of a film capacitor 900 according to an exemplary embodiment is shown. Film capacitor 900 has first or lower planar flexible conductive electrode 910 and second or upper flexible planar conductive electrode 920, on and in contact with opposing faces of flexible dielectric 950. Flexible conductive electrodes 910, 920, may be of any flexible conductive material, such as a foil of aluminum, zinc, copper or gold, or a deposited metalized film of aluminum or other metal. Flexible conductive electrodes 910, 920 are generally planar, generally extending relatively large distances in two dimensions, e.g., width and height, and having a relatively small third, or thickness, dimension. Dielectric 950 is a dielectric structure according to an embodiment of the present disclosure. In the illustrated embodiment, dielectric 950 is a five layer structure having three polymer layers 952, 954, 956, each having no conductive nanoparticles or a low volume density of conductive nanoparticles, with polymer layer 960 having a relatively high volume density of nanoparticles 962 intermediate polymer layers 952, 954, and polymer layer 964 having a relatively high volume density of nanoparticles 966 intermediate polymer layers 954, 956. Polymer layers 952, 954, 956, may each be made up of multiple sublayers of polymers having alternating properties of hydrogen bond donor and hydrogen bond acceptor.

In embodiments, a film capacitor may include more or fewer layers in dielectric 950. For example, dielectric 950 may have only a single polymer layer having a high volume density of nanoparticles, intermediate two polymer layers each having a low volume of nanoparticles or no nanoparticles. Each of the polymer layers may be made up of multiple sublayers of polymers having alternating properties of hydrogen bond donor and hydrogen bond acceptor. In other embodiments, the single polymer layer having a high volume density of nanoparticles may be a single layer of one of a hydrogen bond donor and hydrogen bond acceptor, and the two polymer layers each having a low volume of nanoparticles or no nanoparticles may be single layers of the other of a hydrogen bond donor and hydrogen bond acceptor.

In FIG. 9, nanoparticles 962, 966 are generally shown as spherical objects. In embodiments of the film capacitor 900, nanoparticles may be of any material disclosed herein and any shape, including rods, such as nanotubes, thin and generally planar shapes, such as nanoflakes and nanowalls, as well as irregular shapes.

Film capacitor 900 is flexible, and may be rolled or otherwise manipulated into suitable shapes for any suitable application or package.

While embodiments showing embodiments of a disclosed dielectric structure embodied in a transistor and in a capacitor are illustrated, the illustration of these embodiments is merely exemplary, and does not limit the applications of embodiments of the disclosed dielectric structures.

While the foregoing invention has been described with reference to the above-described embodiment, various modifications and changes can be made without departing from the spirit of the invention. Accordingly, all such modifications and changes are considered to be within the scope of the appended claims. Accordingly, the specification and the drawings are to be regarded in an illustrative rather than a restrictive sense. The accompanying drawings that form a part hereof, show by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

Such embodiments of the inventive subject matter may be referred to herein, individually and/or collectively, by the term “invention” merely for convenience and without intending to voluntarily limit the scope of this application to any single invention or inventive concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations of variations of various embodiments. Combinations of the above embodiments, and other embodiments not specifically described herein, will be apparent to those of skill in the art upon reviewing the above description.

What is claimed is:

1. A flexible dielectric structure, comprising:
a first polymer layer having a low density of nanoparticles;
a second polymer layer on and in contact with the first polymer layer and having a high density of nanoparticles; and
a third polymer layer on and in contact with the second polymer layer and having a low density of nanoparticles.

2. The structure of claim 1, wherein the low density of nanoparticles is less than 5 percent by volume.

3. The structure of claim 2, wherein the low density of nanoparticles is substantially zero.

4. The structure of claim 1, wherein the high density of nanoparticles is at least about 10 percent by volume.

5. The structure of claim 1, wherein the polymer layers each comprise alternating sublayers of polymers having hydrogen bond acceptor properties and polymers having hydrogen bond donor properties.

6. The structure of claim 1, wherein the nanoparticles are conductive.

7. The structure of claim 6, wherein the nanoparticles are at least one of Au, Ag, Al and Cu.

8. The structure of claim 1, wherein the nanoparticles are dielectrics.

9. The structure of claim 8, wherein the nanoparticles are of ceramic.

10. The structure of claim 9, wherein the nanoparticles are at least one of CCTO, BaTiO₃, TiO₂, SiO₂ and Al₂O₃.

11. The structure of claim 1, wherein the nanoparticles are of carbon.

12. The structure of claim 11, wherein the nanoparticles are at least one of carbon nanotubes, carbon onions, graphene, graphitic nanoflakes, carbon black, and carbon nanofibers.

13. The structure of claim 1, wherein the nanoparticles are of conducting polymers.

14. The structure of claim 13, wherein the nanoparticles are at least one of polyaniline (PANI), polypyrrole (PPy), polythiophene (PTh), and polynathylamine (PNA).

15. The structure of claim 1, wherein each of the polymer layers has a thickness of between about 50 nm and about 100 nm.

16. The structure of claim 1, wherein the nanoparticles have a feature size of not greater than about 100 nm.

17. The structure of claim 1, further comprising:
a fourth polymer layer on the third polymer layer and having a high density of nanoparticles; and
a fifth polymer layer on the fourth polymer layer and having a low density of nanoparticles.

18. A method of making a flexible dielectric structure, comprising:
forming a first polymer layer having a low density of nanoparticles;
forming, directly on the first polymer layer, a second polymer layer having a high density of nanoparticles; and
forming, directly on the second polymer layer, a third polymer layer having a low density of nanoparticles.

19. The method of claim 18, wherein the forming comprises one of dip coating, spin coating, spray coating and ink jet printing.

20. The method of claim 18, wherein the first polymer layer comprises alternating sublayers of poly(ethylene oxide) and of one of poly(methacrylic acid) and poly(acrylic acid).

21. The method of claim 18, further comprising forming a fourth polymer layer directly on the third polymer layer, the fourth polymer layer having a high density of nanoparticles; and forming a fifth polymer layer directly on the fourth polymer layer, the fifth polymer layer having a low density of nanoparticles.

22. The method of claim 18, wherein the nanoparticles comprise elongated rods, and further comprising aligning the elongated rods in each layer having a high density of nanoparticles.

23. A transistor on a flexible substrate, comprising:
a gate formed on the flexible substrate;
a gate dielectric on the gate, and comprising:
a first polymer layer having a low density of nanoparticles;
a second polymer layer on the first polymer layer and having a high density of nanoparticles; and
a third polymer layer on the second polymer layer and having a low density of nanoparticles; and
a source, drain, and semiconductor material formed on the gate dielectric.

24. The transistor of claim 23, wherein the first and third polymer layers have substantially no nanoparticles.

25. The transistor of claim 24, wherein the gate dielectric further comprises:
a fourth polymer layer on the third polymer layer and having a high density of nanoparticles;
a fifth polymer layer on the fourth polymer layer and having substantially no nanoparticles;
a sixth polymer layer on the third polymer layer and having a high density of nanoparticles; and
a seventh polymer layer on the sixth polymer layer and having substantially no nanoparticles.

26. A film capacitor, comprising:
a flexible dielectric comprising:
a first polymer layer having a low density of nanoparticles;
a second polymer layer on the first polymer layer and having a high density of nanoparticles; and
a third polymer layer on the second polymer layer and having a low density of nanoparticles; and
first and second planar flexible conductive electrodes on opposing faces of the flexible dielectric.

27. The film capacitor of claim 26, wherein the polymer layers comprise alternating sublayers of polymers having hydrogen bond acceptor properties and polymers having hydrogen bond donor properties.
